(19) United States
(12) Patent Application Publication
(10) Pub. No.: US 2024/0055518 A1
(43) Pub. Date: Feb. 15, 2024

(54) TRANSISTOR, INTEGRATED CIRCUIT, AND MANUFACTURING METHOD OF TRANSISTOR

(71) Applicant: Taiwan Semiconductor Manufacturing Company, Ltd., Hsinchu (TW)

(72) Inventors: Georgios Vellianitis, Heverlee (BE); Sai-Hooi Yeong, Hsinchu County (TW)

(73) Assignee: Taiwan Semiconductor Manufacturing Company, Ltd., Hsinchu (TW)

(21) Appl. No.: 17/887,490

(22) Filed: Aug. 14, 2022

(51) Int. Cl. H01L 29/78; H01L 27/1159; H01L 29/786; H01L 29/66

(52) U.S. Cl. CPC H01L 29/78391; H01L 27/1159; H01L 29/78606; H01L 29/7869; H01L 29/78696; H01L 29/66969

(57) ABSTRACT

A transistor includes a gate electrode, a ferroelectric layer, a source pattern, a drain pattern, and a channel layer. The ferroelectric layer is disposed on the gate electrode. The source pattern and the drain pattern are disposed over the ferroelectric layer. The channel layer has a base and fins protruding from the base. The base is in contact with the ferroelectric layer. The fins are located between the source pattern and the drain pattern.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an integrated circuit in accordance with some embodiments of the disclosure.

FIG. 2A to FIG. 2Q are cross-sectional views illustrating various stages of the manufacturing method of the second transistor in FIG. 1 in accordance with some embodiments of the disclosure.

FIG. 3 is a cross-sectional view of the second transistor in FIG. 1 in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

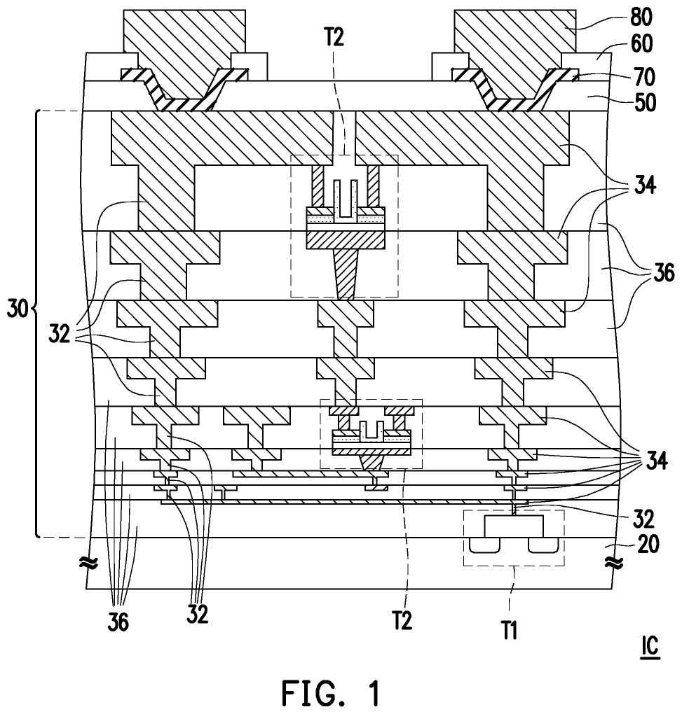

FIG. 1 is a schematic cross-sectional view of an integrated circuit IC in accordance with some embodiments of the disclosure. In some embodiments, the integrated circuit IC includes a substrate 20, an interconnect structure 30, a passivation layer 50, a post-passivation layer 60, a plurality of conductive pads 70, and a plurality of conductive terminals 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as source/drain regions of a first transistor T1, which is over the substrate 20. Depending on the types of the dopants in the doped regions, the first transistor T1 may be referred to as n-type transistor or p-type transistor. In some embodiments, the first transistor T1 further includes a metal gate and a channel under the metal gate. The channel is located between the source region and the drain region to serve as a path for electron to travel when the first transistor T1 is turned on. On the other hand, the metal gate is located above the substrate 20 and is embedded in the interconnect structure 30. In some embodiments, the first transistor T1 is formed using suitable Front-end-of-line (FEOL) process. For simplicity, one first transistor T1 is shown in FIG. 1. However, it should be understood that more than one first transistors T1 may be presented depending on the application of the integrated circuit IC. When multiple first transistors T1 are presented, these first transistors T1 may be separated by shallow trench isolation (STI; not shown) located between two adjacent first transistors T1.

As illustrated in FIG. 1, the interconnect structure 30 is disposed on the substrate 20. In some embodiments, the interconnect structure 30 includes a plurality of conductive vias 32, a plurality of conductive patterns 34, a plurality of dielectric layers 36, and a plurality of second transistors T2. As illustrated in FIG. 1, the conductive patterns 34 and the conductive vias 32 are embedded in the dielectric layers 36. In some embodiments, the conductive patterns 34 located at different level heights are connected to one another through the conductive vias 32. In other words, the conductive patterns 34 are electrically connected to one another through the conductive vias 32. In some embodiments, the bottommost conductive vias 32 are connected to the first transistor T1. For example, the bottommost conductive vias 32 are connected to the metal gate, which is embedded in the bottommost dielectric layer 36, of the first transistor T1. In other words, the bottommost conductive vias 32 establish electrical connection between the first transistor T1 and the conductive patterns 34 of the interconnect structure 30. It should be noted that in some alternative cross-sectional views, other bottommost conductive vias 32 are also connected to source/drain regions of the first transistor T1. That is, in some embodiments, the bottommost conductive vias 32 may be referred to as “contact structures” of the first transistor T1.

In some embodiments, a material of the dielectric layers 36 includes polyimide, epoxy resin, acrylic resin, phenol resin, benzocyclobutene (BCB), polybenzooxazole (PBO), or any other suitable polymer-based dielectric material. Alternatively, the dielectric layers 36 may be formed of oxides or nitrides, such as silicon oxide, silicon nitride, aluminum oxide, hafnium oxide, hafnium zirconium oxide, or the like. In some embodiments, different dielectric layers 36 are formed by the same material. However, the disclosure is not limited thereto. In some alternative embodiments, different dielectric layers 36 may be formed by different materials. The dielectric layers 36 may be formed by suitable fabrication techniques, such as spin-on coating, chemical vapor deposition (CVD), plasma-enhanced chemical vapor deposition (PECVD), or the like.

In some embodiments, a material of the conductive patterns 34 and the conductive vias 32 includes aluminum, titanium, copper, nickel, tungsten, or alloys thereof. The conductive patterns 34 and the conductive vias 32 may be formed by electroplating, deposition, and/or photolithography and etching. In some embodiments, the conductive patterns 34 and the underlying conductive vias 32 are formed simultaneously. It should be noted that the number of the dielectric layers 36, the number of the conductive patterns 34, and the number of the conductive vias 32 illustrated in FIG. 1 are merely for illustrative purposes, and the disclosure is not limited thereto. In some alternative embodiments, fewer or more layers of the dielectric layers 36, the conductive patterns 34, and/or the conductive vias 32 may be formed depending on the circuit design.

In some embodiments, the second transistors T2 are embedded in the interconnect structure 30. For example, the second transistors T2 are embedded in the dielectric layers 36. In some embodiments, the second transistors T2 are electrically connected to the conductive patterns 34 through the corresponding conductive vias 32. The formation method and the structure of the second transistors T2 will be described in detail later.

As illustrated in FIG. 1, the passivation layer 50, the conductive pads 70, the post-passivation layer 60, and the conductive terminals 80 are sequentially formed on the interconnect structure 30. In some embodiments, the passivation layer 50 is disposed on the topmost dielectric layer 36 and the topmost conductive patterns 34. In some embodiments, the passivation layer 50 has a plurality of openings partially exposing each topmost conductive pattern 34. In some embodiments, the passivation layer 50 is a silicon oxide layer, a silicon nitride layer, a silicon oxynitride layer, or a dielectric layer formed by other suitable dielectric materials. The passivation layer 50 may be formed by suitable fabrication techniques, such as high density plasma chemical vapor deposition (HDP-CVD), PECVD, or the like.

In some embodiments, the conductive pads 70 are formed over the passivation layer 50. In some embodiments, the conductive pads 70 extend into the openings of the passivation layer 50 to be in direct contact with the topmost conductive patterns 34. That is, the conductive pads 70 are electrically connected to the interconnect structure 30. In some embodiments, the conductive pads 70 include aluminum pads, copper pads, titanium pads, nickel pads, tungsten pads, or other suitable metal pads. The conductive pads 70 may be formed by, for example, electroplating, deposition, and/or photolithography and etching. It should be noted that the number and the shape of the conductive pads 70 illustrated in FIG. 1 are merely for illustrative purposes, and the disclosure is not limited thereto. In some alternative embodiments, the number and the shape of the conductive pad 70 may be adjusted based on demand.

In some embodiments, the post-passivation layer 60 is formed over the passivation layer 50 and the conductive pads 70. In some embodiments, the post-passivation layer 60 is formed on the conductive pads 70 to protect the conductive pads 70. In some embodiments, the post-passivation layer 60 has a plurality of contact openings partially exposing each conductive pad 70. The post-passivation layer 60 may be a polyimide layer, a PBO layer, or a dielectric layer formed by other suitable polymers. In some embodiments, the post-passivation layer 60 is formed by suitable fabrication techniques, such as HDP-CVD, PECVD, or the like.

As illustrated in FIG. 1, the conductive terminals 80 are formed over the post-passivation layer 60 and the conductive pads 70. In some embodiments, the conductive terminals 80 extend into the contact openings of the post-passivation layer 60 to be in direct contact with the corresponding conductive pad 70. That is, the conductive terminals 80 are electrically connected to the interconnect structure 30 through the conductive pads 70. In some embodiments, the conductive terminals 80 are conductive pillars, conductive posts, conductive balls, conductive bumps, or the like. In some embodiments, a material of the conductive terminals 80 includes a variety of metals, metal alloys, or metals and mixture of other materials. For example, the conductive terminals 80 may be made of aluminum, titanium, copper, nickel, tungsten, tin, and/or alloys thereof. The conductive terminals 80 are formed by, for example, deposition, electroplating, screen printing, or other suitable methods. In some embodiments, the conductive terminals 80 are used to establish electrical connection with other components (not shown) subsequently formed or provided.

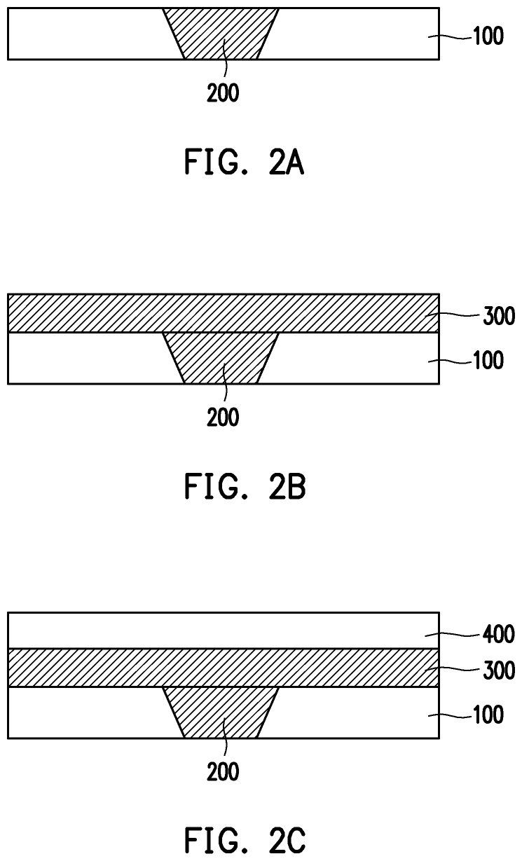

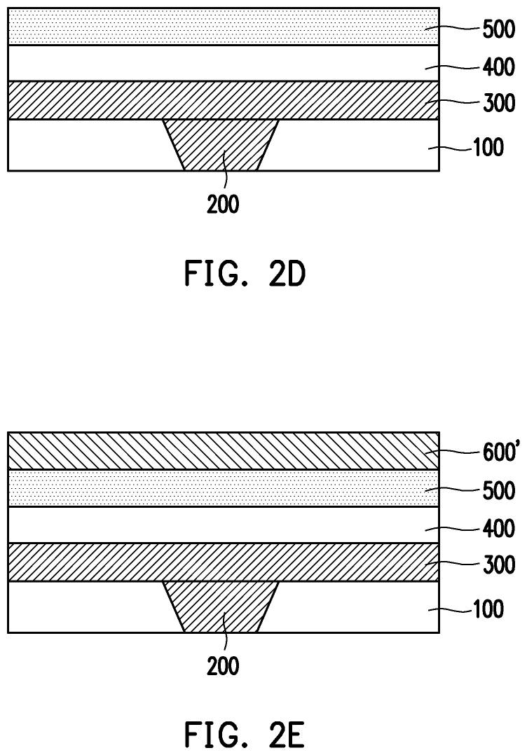

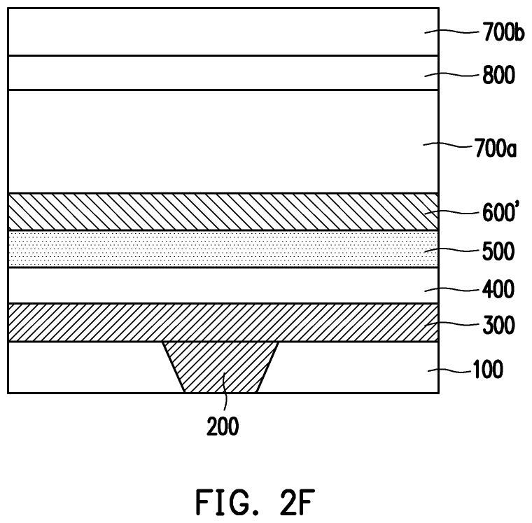

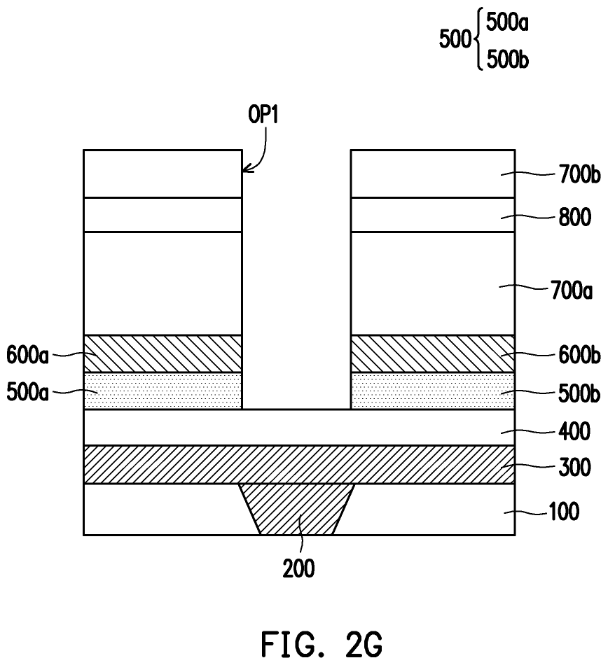

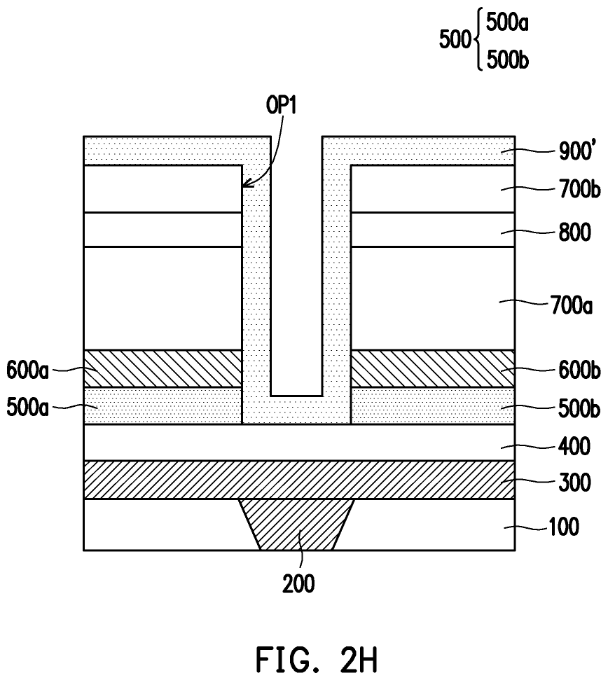

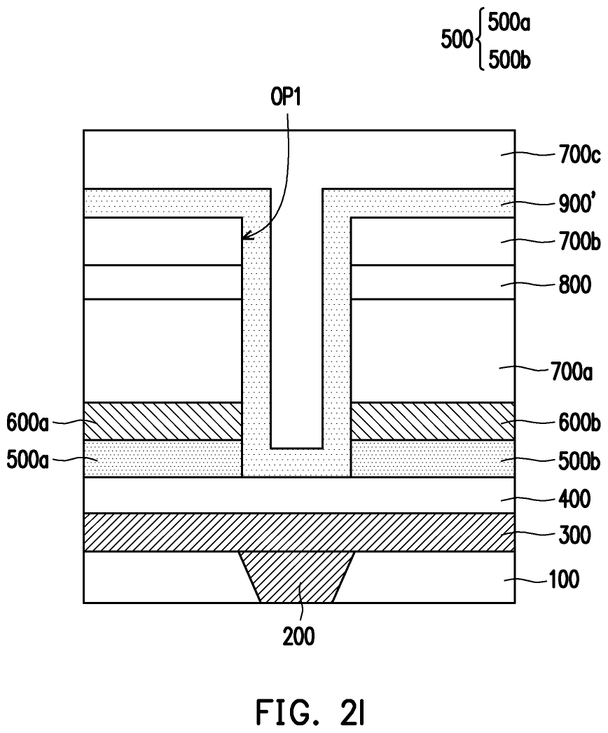

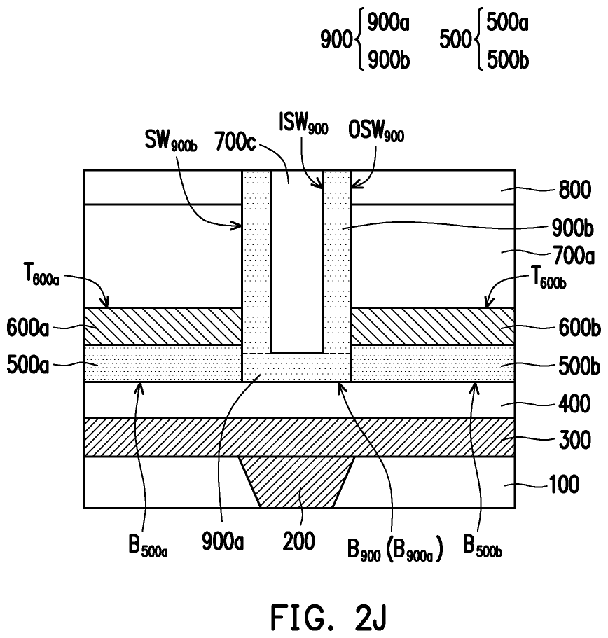

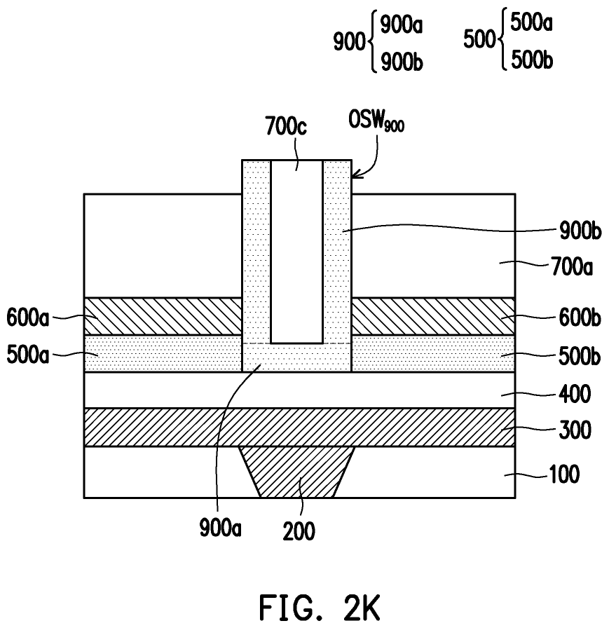

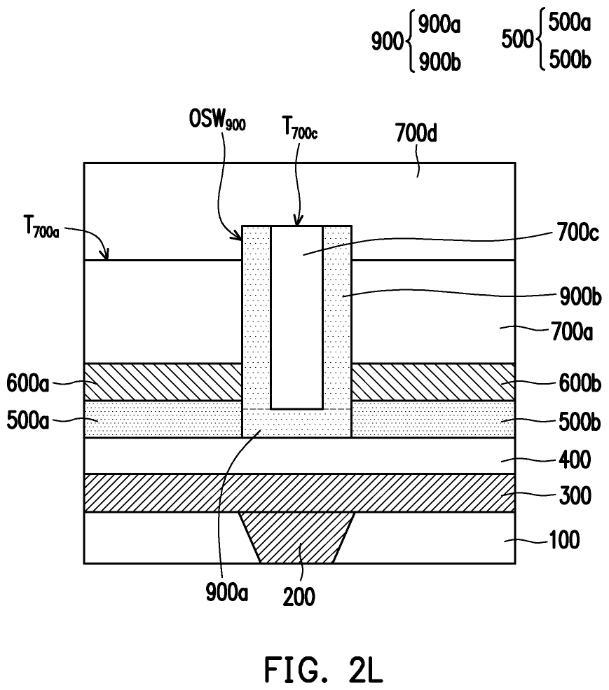

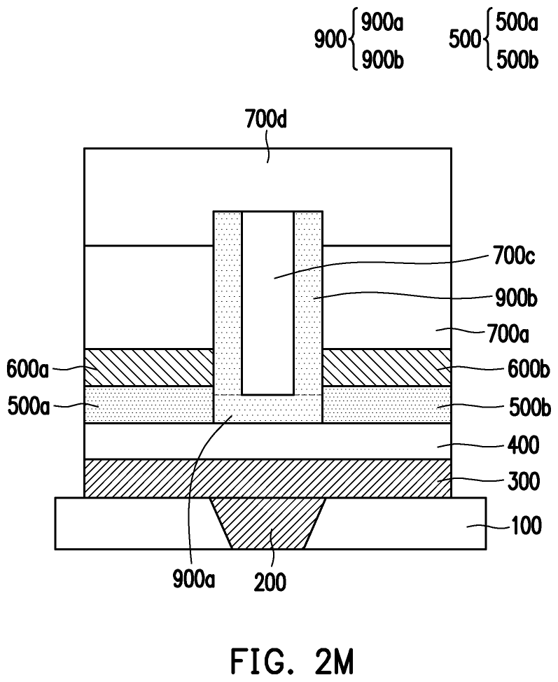

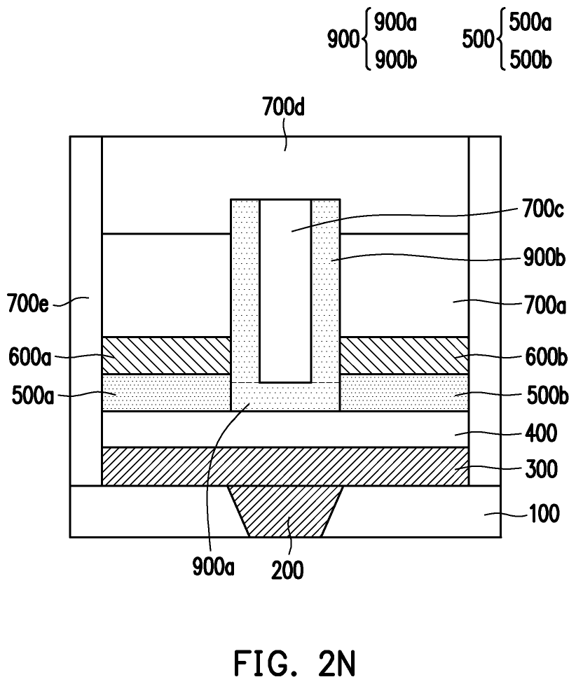

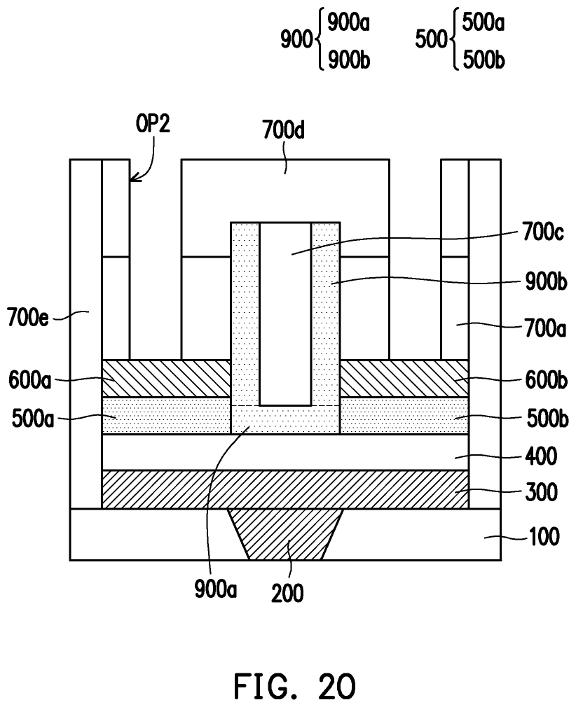

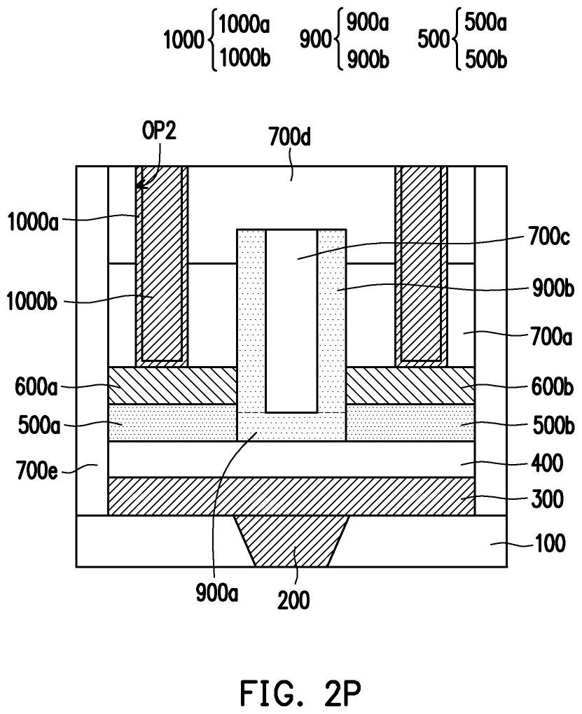

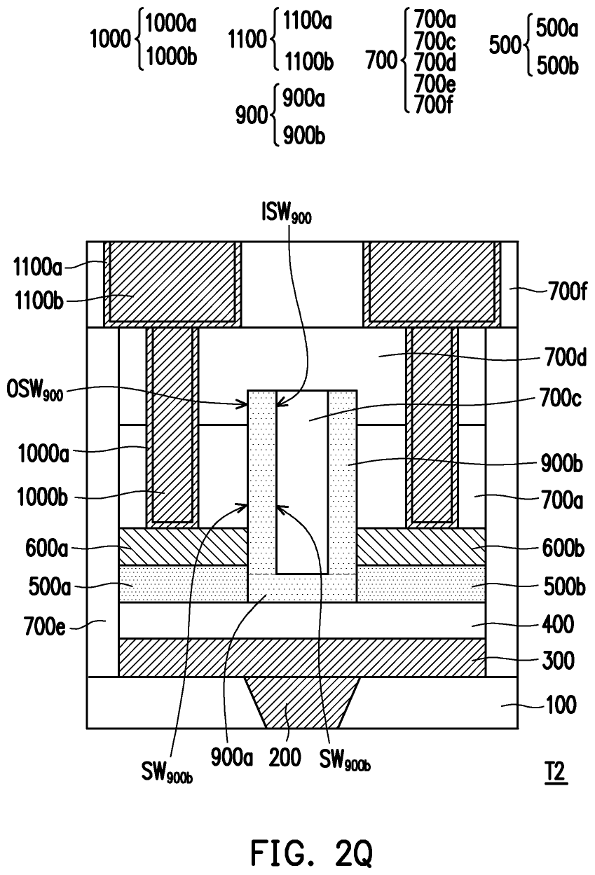

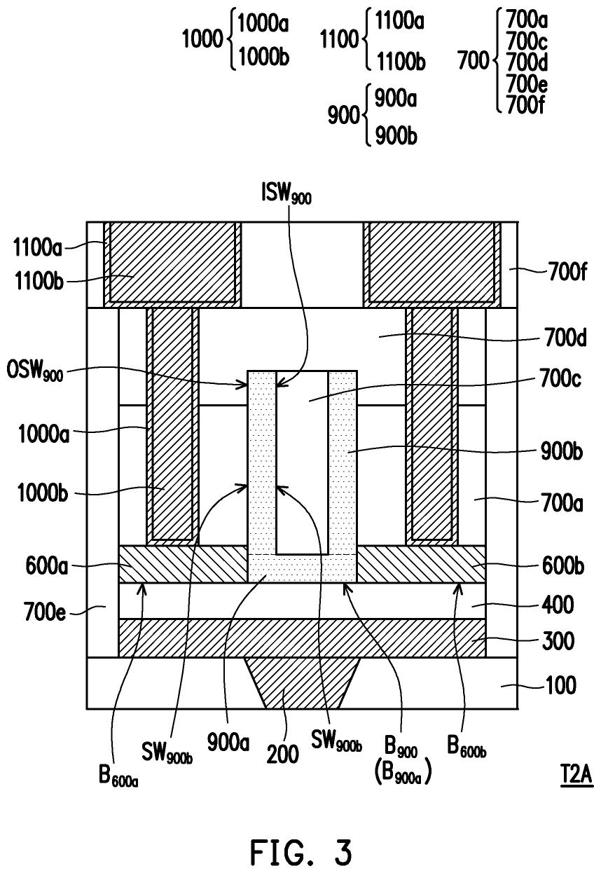

As mentioned above, the second transistors T2 are embedded in the interconnect structure 30. Taking the topmost second transistor T2 shown in FIG. 1 as an example, the formation method and the structure of this second transistor T2 will be described below in conjunction with FIG. 2A to FIG. 2Q and FIG. 3.

FIG. 2A to FIG. 2Q are cross-sectional views illustrating various stages of the manufacturing method of the second transistor T2 in FIG. 1 in accordance with some embodiments of the disclosure.

Referring to FIG. 2A, a dielectric layer 100 is provided. In some embodiments, the dielectric layer 100 is a part of one of the dielectric layers 36 of the interconnect structure 30 of FIG. 1, so the detailed description thereof is omitted herein. As illustrated in FIG. 2A, a conductive via 200 is embedded in the dielectric layer 100. In some embodiments, the conductive via 200 is one of the conductive vias 32 of the interconnect structure 30 of FIG. 1, so the detailed description thereof is omitted herein. In some embodiments, the conductive via 200 may serve as a word line for the subsequently formed memory cells. In some embodiments, the conductive via 200 electrically connects the subsequently formed second transistor T2 with other elements in the interconnect structure 30.

Referring to FIG. 2B, a gate electrode 300 is formed on the dielectric layer 100 and the conductive via 200. In some embodiments, the gate electrode 300 is one of the conductive patterns 34 of the interconnect structure 30 of FIG. 1. In some embodiments, the gate electrode 300 includes copper, titanium, tantalum, tungsten, aluminum, zirconium, hafnium, cobalt, titanium aluminum, tantalum aluminum, tungsten aluminum, zirconium aluminum, hafnium aluminum, titanium nitride, any other suitable metal-containing material, or a combination thereof. In some embodiments, the gate electrode 300 also includes materials to fine-tune the corresponding work function. For example, the gate electrode 300 may also include p-type work function materials such as Ru, Mo, WN, ZrSi₂, MoSi₂, TaSi₂, NiSi₂, or combinations thereof, or n-type work function materials such as Ag, TaCN, Mn, or combinations thereof. In some embodiments, the gate electrode 300 is deposited through atomic layer deposition (ALD), CVD, physical vapor deposition (PVD), or the like. It should be noted that although FIG. 2A and FIG. 2B illustrated that the conductive via 200 and the gate electrode 300 are formed in different steps, the disclosure is not limited thereto. In some alternative embodiments, the conductive via 200 and the gate electrode 300 may be formed simultaneously in a same step.

In some embodiments, a barrier layer (not shown) is optionally formed between the conductive via 200 and the dielectric layer 100 and between the gate electrode 300 and the dielectric layer 100, so as to avoid diffusion of atoms between elements. In some embodiments, materials of the barrier layer include titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), or a combination thereof.

Referring to FIG. 2C, a ferroelectric layer 400 is formed on the gate electrode 300. In some embodiments, a material of the ferroelectric layer 400 includes AlOₓ, HfOₓ, HfZrOₓ, SiOₓ, a combination thereof, or the like. In some embodiments, the ferroelectric layer 400 is formed through a plasma deposition process such as PVD, PECVD, or the like. However, the disclosure is not limited thereto. In some alternative embodiments, the ferroelectric layer 400 may be formed through a non-plasma deposition process. The non-plasma deposition process denotes a deposition process which does not involve the introduction of plasma. The non-plasma deposition process includes, for example, ALD, CVD, or the like. In some embodiments, the ferroelectric layer 400 is deposited at a temperature ranging from about 200° C. to about 400° C. In some embodiments, the ferroelectric layer 400 may serve as a gate dielectric layer for the subsequently formed second transistor T2.

Referring to FIG. 2D, a hydrogen blocking layer 500 is formed on the ferroelectric layer 400. In some embodiments, the hydrogen blocking layer 500 is made of IXO materials. For example, materials of the hydrogen blocking layer 500 include InO, InSnO, InZnO, or any other oxide semiconductor material that has good affinity with hydrogen atoms. In some embodiments, during the manufacturing process of the subsequently formed second transistor T2, process gases with hydrogen atoms therein are widely used. In addition, the materials for the subsequently deposited dielectric layer may also contain hydrogen atoms therein. In some embodiments, these hydrogen atoms may diffuse freely within the second transistor T2, and the subsequently formed channel layer is likely to react with these hydrogen atoms to create O-vacancies, thereby leading to strong negative threshold voltage shifts in the channel layer. Nevertheless, these negative threshold voltage shifts would jeopardize the performance of the second transistor T2. In some embodiments, the hydrogen blocking layer 500 is able to block the hydrogen atoms from diffusing into the subsequently formed channel layer. For example, since the hydrogen blocking layer 500 has good affinity with the hydrogen atoms, the hydrogen blocking layer 500 is able to hold/trap the hydrogen atoms within the hydrogen blocking layer 500, thereby preventing the hydrogen atoms from diffusing into the subsequently formed channel layer. In some embodiments, since the hydrogen atoms are trapped in the hydrogen blocking layer 500, the hydrogen blocking layer 500 may be referred to as a “hydrogen trapping layer.” In some embodiments, the hydrogen blocking layer 500 is deposited through PVD, PECVD, ALD, CVD, or the like. In some embodiments, the hydrogen blocking layer 500 is optional.

Referring to FIG. 2E, a source/drain material layer 600′ is formed on the hydrogen blocking layer 500. For example, the source/drain material layer 600′ is formed such that the hydrogen blocking layer 500 is located between the ferroelectric layer 400 and the source/drain material layer 600. In some embodiments, the source/drain material layer 600′ is made of cobalt, tungsten, copper, titanium, tantalum, aluminum, zirconium, hafnium, a combination thereof, or other suitable metallic materials. In some embodiments, the source/drain material layer 600′ is formed through CVD, ALD, plating, or other suitable deposition techniques.

Referring to FIG. 2F, a first dielectric layer 700a, an etch stop layer 800, and a second dielectric layer 700b are sequentially formed on the source/drain material layer 600′. For example, the etch stop layer 800 is sandwiched between the first dielectric layer 700a and the second dielectric layer 700b. In some embodiments, the first dielectric layer 700a is a part of one of the dielectric layers 36 of the interconnect structure 30 of FIG. 1, so the detailed description thereof is omitted herein. On the other hand, a material of the second dielectric layer 700b is similar to that of the first dielectric layer 700a, so the detailed description thereof is also omitted herein. In some embodiments, the etch stop layer 800 includes silicon carbide, silicon nitride, silicon oxynitride, silicon carbo-nitride, or multi-layers thereof. In some embodiments, the first dielectric layer 700a and the second dielectric layer 700b are formed by suitable fabrication techniques, such as spin-on coating, CVD, PECVD, or the like. On the other hand, the etch stop layer 800 is deposited using CVD, HDP-CVD, sub-atmospheric chemical vapor deposition (SACVD), molecular layer deposition (MLD), or other suitable methods.

Referring to FIG. 2F and FIG. 2G, the second dielectric layer 700b, the etch stop layer 800, the first dielectric layer 700a, the source/drain material layer 600′, and the hydrogen blocking layer 500 are patterned to form an opening OP1 penetrating through the second dielectric layer 700b, the etch stop layer 800, the first dielectric layer 700a, the source/drain material layer 600′, and the hydrogen blocking layer 500. For example, a portion of the second dielectric layer 700b, a portion of the etch stop layer 800, a portion of the first dielectric layer 700a, a portion of the source/drain material layer 600′, and a portion of the hydrogen blocking layer 500 are removed to form the opening OP1. In some embodiments, the second dielectric layer 700b, the etch stop layer 800, the first dielectric layer 700a, the source/drain material layer 600′, and the hydrogen blocking layer 500 are patterned simultaneously through a photolithography and etching process. For example, a patterned photoresist layer (not shown) is formed on the second dielectric layer 700b. Thereafter, an etching process is performed to remove the portion of the second dielectric layer 700b, the portion of the etch stop layer 800, the portion of the first dielectric layer 700a, the portion of the source/drain material layer 600′, and the portion of the hydrogen blocking layer 500 that are not covered/shielded by the patterned photoresist layer. The etching process includes, for example, an anisotropic etching process such as dry etch or an isotropic etching process such as wet etch. Subsequently, the patterned photoresist layer is removed through a stripping process or the like to expose the remaining second dielectric layer 700b.

As illustrated in FIG. 2G, the opening OP1 exposes a portion of the ferroelectric layer 400. In some embodiments, the source/drain material layer 600′ is patterned to form a source pattern 600a and a drain pattern 600b. In some embodiments, the source pattern 600a and the drain pattern 600b are spatially separated from each other by the opening OP1. For example, the source pattern 600a and the drain pattern 600b are respectively located at two opposite sides of the opening OP1. In some embodiments, the opening OP1 divides the hydrogen blocking layer 500 into a first hydrogen blocking pattern 500a and a second hydrogen blocking pattern 500b. For example, the first hydrogen blocking pattern 500a and the second hydrogen blocking pattern 500b are spatially separated from each other by the opening OP1. As illustrated in FIG. 2G, the first hydrogen blocking pattern 500a and the second hydrogen blocking pattern 500b are respectively located at two opposite sides of the opening OP1.

In some embodiments, the first hydrogen blocking pattern 500a, the second hydrogen blocking pattern 500b, the source pattern 600a, and the drain pattern 600b are disposed over the ferroelectric layer 400. For example, the first hydrogen blocking pattern 500a is sandwiched between the source pattern 600a and the ferroelectric layer 400. Meanwhile, the second hydrogen blocking pattern 500b is sandwiched between the drain pattern 600b and the ferroelectric layer 400. In other words, the hydrogen blocking layer 500 is sandwiched between the source pattern 600a and the ferroelectric layer 400 and between the drain pattern 600b and the ferroelectric layer 400.

Referring to FIG. 2H, a channel material layer 900′ is conformally deposited on the second dielectric layer 700b and in the opening OP1. For example, the channel material layer 900′ covers a top surface of the second dielectric layer 700b, sidewalls of the opening OP1, and a bottom surface of the opening OP1. In some embodiments, the channel material layer 900′ does not completely fill up the opening OP1. For example, the channel material layer 900′ exhibits a U-shape from the cross-sectional view in FIG. 2H. In some embodiments, the channel material layer 900′ extends into the opening OP1 to be in physical contact with the second dielectric layer 700b, the etch stop layer 800, the first dielectric layer 700a, the source pattern 600a, the drain pattern 600b, the first hydrogen blocking pattern 500a, the second hydrogen blocking pattern 500b, and the ferroelectric layer 400. In some embodiments, the channel material layer 900′ includes metal oxide materials. Examples of the metal oxide materials include IGZOₓ, InZnOₓ, InWOₓ, InOₓ, the like, or a combination thereof. In some embodiments, these metal oxide materials are also being referred to as oxide semiconductor materials. In some embodiments, the channel material layer 900′ is made of a single layer having one of the foregoing materials. However, the disclosure is not limited thereto. In some alternative embodiments, the channel material layer 900′ may be made of a laminate structure of at least two of the foregoing materials. In some embodiments, the channel material layer 900′ is doped with a dopant to achieve extra stability. In some embodiments, the channel material layer 900′ is deposited by suitable techniques, such as CVD, ALD, PVD, PECVD, epitaxial growth, or the like.

Referring to FIG. 2I, a third dielectric layer 700c is formed on the channel material layer 900′ and in the opening OP1. For example, the third dielectric layer 700c covers a top surface of the channel material layer 900′. In some embodiments, the third dielectric layer 700c extends into the opening OP1 to completely fill up the opening OP1. In some embodiments, the third dielectric layer 700c is a part of one of the dielectric layers 36 of the interconnect structure 30 of FIG. 1, so the detailed description thereof is omitted herein.

Referring to FIG. 2I and FIG. 2J, a portion of the third dielectric layer 700c, a portion of the channel material layer 900′, and the second dielectric layer 700b are removed until the etch stop layer 800 is exposed to form a channel layer 900. For example, the portion of the third dielectric layer 700c and the portion of the channel material layer 900′ that are located above the etch stop layer 800 are removed. Meanwhile, the second dielectric layer 700b is completely removed. In some embodiments, the portion of the third dielectric layer 700c, the portion of the channel material layer 900′, and the second dielectric layer 700b are removed through a grinding process, such as a mechanical grinding process, a chemical mechanical polishing (CMP) process, or the like. In some embodiments, the etch stop layer 800 serves as a stopping layer for the grinding process. That is, the grinding process is stopped when the etch stop layer 800 is revealed.

In some embodiments, the channel layer 900 exhibits a U-shape from the cross-sectional view in FIG. 2J. For example, the channel layer 900 has a pair of inner sidewalls ISW₉₀₀ and a pair of outer sidewalls OSW₉₀₀ opposite to the inner sidewalls ISW₉₀₀. In some embodiments, the inner sidewalls ISW₉₀₀ face each other, while the outer sidewalls OSW₉₀₀ face opposite directions. As illustrated in FIG. 2J, the third dielectric layer 700c is in physical contact with the inner sidewalls ISW₉₀₀ of the channel layer 900. On the other hand, the etch stop layer 800, the first dielectric layer 700a, the source pattern 600a, the drain pattern 600b, the first hydrogen blocking pattern 500a, and the second hydrogen blocking pattern 500b are in physical contact with the outer sidewalls OSW₉₀₀ of the channel layer 900. For example, the first hydrogen blocking pattern 500a and the second hydrogen blocking pattern 500b are respectively in physical contact with opposite outer sidewalls OSW₉₀₀ of the channel layer 900. Similarly, the source pattern 600a and the drain pattern 600b are respectively in physical contact with opposite outer sidewalls OSW₉₀₀ of the channel layer 900.

As illustrated in FIG. 2J, the channel layer 900 has a base 900a and fins 900b protruding from the base 900a. In some embodiments, the fins 900b extend from the base 900a to beyond a top surface T₆₀₀ₐ of the source pattern 600a and a top surface T_{600b} of the drain pattern 600b. In some embodiments, the base 900a is in physical contact with the ferroelectric layer 400. In addition, the base 900a is sandwiched between the first hydrogen blocking pattern 500a and the second hydrogen blocking pattern 500b. In some embodiments, the fins 900b are located between the first hydrogen blocking pattern 500a and the second hydrogen blocking pattern 500b and between the source pattern 600a and the drain pattern 600b. For example, a portion of each fin 900b is located between the first hydrogen blocking pattern 500a and the second hydrogen blocking pattern 500b. On the other hand, another portion of each fin 900b is located between the source pattern 600a and the drain pattern 600b. As illustrated in FIG. 2J, the first hydrogen blocking pattern 500a and the second hydrogen blocking pattern 500b are in physical contact with the base 900a and the fins 900b. Meanwhile, the source pattern 600a and the drain pattern 600b are in physical contact with the fins 900b. For example, the source pattern 600a and the drain pattern 600b are in physical contact with a sidewall SW_{900b} of the fin 900b.

In some embodiments, a bottom surface B₉₀₀ of the channel layer 900 is coplanar with a bottom surface of the hydrogen blocking layer 500. For example, a bottom surface B₉₀₀ₐ of the base 900a is coplanar with a bottom surface B₅₀₀ₐ of the first hydrogen blocking pattern 500a and a bottom surface B_{500b} of the second hydrogen blocking pattern 500b.

As illustrated in FIG. 2J, the source pattern 600a, the first hydrogen blocking pattern 500a, the ferroelectric layer 400, and the gate electrode 300 are vertically overlapped with one another. Similarly, the drain pattern 600b, the second hydrogen blocking pattern 600b, the ferroelectric layer 400, and the gate electrode 300 are also vertically overlapped with one another. In some embodiments, the overlapping of these elements allows the formation of memory cells in the subsequently formed second transistor T2. That is, memory cells are integrated within the second transistor T2. The configurations of these memory cells will be described below.

In some embodiments, the source pattern 600a, the first hydrogen blocking pattern 500a, the ferroelectric layer 400, and the gate electrode 300 collectively form a first memory cell. On the other hand, the drain pattern 600b, the second hydrogen blocking pattern 500b, the ferroelectric layer 400, and the gate electrode 300 collectively form a second memory cell. In some embodiments, due to its material characteristics, the ferroelectric layer 400 may be utilized to trap electrons. For example, the ferroelectric layer 400 may be utilized to store data. As such, in some embodiments, the ferroelectric layer 400 is referred to as a “storage layer.” In some embodiments, the source pattern 600a and the gate electrode 300 respectively serve as a top electrode and a bottom electrode of the first memory cell. Meanwhile, the ferroelectric layer 400 may serve as a storage layer of the first memory cell. Similarly, the drain pattern 600b and the gate electrode 300 respectively serve as a top electrode and a bottom electrode of the second memory cell. Meanwhile, the ferroelectric layer 400 may serve as a storage layer of the second memory cell. In some embodiments, the first memory cell and the second memory cell share a common bottom electrode (i.e. the gate electrode 300) and a common storage layer (i.e. the ferroelectric layer 400). In some embodiments, since the storage layers of the first memory cell and the second memory cell are made of ferroelectric materials, the first memory cell and the second memory cell may be considered as memory cells for a FeRAM (Ferroelectric Random Access Memory).

Conventionally, in a transistor having a memory cell, a channel layer is disposed between a top electrode/bottom electrode and a storage layer. However, the thickness of this channel layer would result in longer distance between the top electrode/bottom electrode and the storage layer, thereby weakening the electric field from the top electrode/bottom electrode to the storage layer. As a result, the efficiency and the performance of the memory cell are compromised. However, as illustrated in FIG. 2J, the channel layer 900 is disposed on the ferroelectric layer 400. In addition, the channel layer 900 is disposed aside the source pattern 600a and the drain pattern 600b. In other words, the channel layer 900 is not located vertically between the source pattern 600a/drain pattern 600b and the ferroelectric layer 400. That is, a distance between the top electrode (i.e. the source pattern 600a and the drain pattern 600b) and the storage layer (i.e. the ferroelectric layer 400) is rather short to provide a strong electric field from the top electrode (i.e. the source pattern 600a and the drain pattern 600b) to the storage layer (i.e. the ferroelectric layer 400). As such, the configuration of the channel layer 900 as shown in FIG. 2J may enhance the efficiency and the performance of the memory cells in the subsequently formed second transistor T2.

Referring to FIG. 2J and FIG. 2K, the etch stop layer 800 is removed. In some embodiments, the etch stop layer 800 is removed through an etching process. The etching process includes, for example, an anisotropic etching process such as dry etch or an isotropic etching process such as wet etch. It should be noted that during the etching process for removing the etch stop layer 800, the third dielectric layer 700c and the channel layer 900 are not damaged. After the etch stop layer 800 is removed, the first dielectric layer 700a is revealed and a portion of each outer sidewall OSW₉₀₀ is exposed.

Referring to FIG. 2L, a fourth dielectric layer 700d is formed on the first dielectric layer 700a, the channel layer 900, and the third dielectric layer 700c. For example, the fourth dielectric layer 700d is formed to cover a top surface T₇₀₀ₐ of the first dielectric layer 700a, a top surface T_{700c} of the third dielectric layer 700c, and the exposed portion of the outer sidewalls OSW₉₀₀ of the channel layer 900. In some embodiments, the fourth dielectric layer 700d is a part of one of the dielectric layers 36 of the interconnect structure 30 of FIG. 1, so the detailed description thereof is omitted herein.

Referring to FIG. 2L and FIG. 2M, the fourth dielectric layer 700d, the first dielectric layer 700a, the source pattern 600a, the drain pattern 600b, the first hydrogen blocking pattern 500a, the second hydrogen blocking pattern 500b, the ferroelectric layer 400, and the gate electrode 300 are patterned to exposed at least a portion of the dielectric layer 100. In some embodiments, the fourth dielectric layer 700d, the first dielectric layer 700a, the source pattern 600a, the drain pattern 600b, the first hydrogen blocking pattern 500a, the second hydrogen blocking pattern 500b, the ferroelectric layer 400, and the gate electrode 300 are patterned through a photolithography and etching process. For example, a patterned photoresist layer (not shown) is formed on the fourth dielectric layer 700d shown in FIG. 2L to define the shape of the fourth dielectric layer 700d, the first dielectric layer 700a, the source pattern 600a, the drain pattern 600b, the first hydrogen blocking pattern 500a, the second hydrogen blocking pattern 500b, the ferroelectric layer 400, and the gate electrode 300 shown in FIG. 2M. Thereafter, an etching process is performed to remove the fourth dielectric layer 700d, the first dielectric layer 700a, the source pattern 600a, the drain pattern 600b, the first hydrogen blocking pattern 500a, the second hydrogen blocking pattern 500b, the ferroelectric layer 400, and the gate electrode 300 that are not covered by the patterned photoresist layer. The etching process includes, for example, an anisotropic etching process such as dry etch or an isotropic etching process such as wet etch. Then, the patterned photoresist layer is removed through a stripping process or the like to obtain the fourth dielectric layer 700d, the first dielectric layer 700a, the source pattern 600a, the drain pattern 600b, the first hydrogen blocking pattern 500a, the second hydrogen blocking pattern 500b, the ferroelectric layer 400, and the gate electrode 300 shown in FIG. 2M. In some embodiments, the fourth dielectric layer 700d, the first dielectric layer 700a, the source pattern 600a, the drain pattern 600b, the first hydrogen blocking pattern 500a, the second hydrogen blocking pattern 500b, the ferroelectric layer 400, and the gate electrode 300 are patterned simultaneously through the same process, so a sidewall of the fourth dielectric layer 700d, a sidewall of the first dielectric layer 700a, a sidewall of the source pattern 600a, a sidewall of the first hydrogen blocking pattern 500a, a sidewall of the ferroelectric layer 400, and a sidewall of the gate electrode 300 are aligned. Meanwhile, a sidewall of the fourth dielectric layer 700d, a sidewall of the first dielectric layer 700a, a sidewall of the drain pattern 600b, a sidewall of the second hydrogen blocking pattern 500b, a sidewall of the ferroelectric layer 400, and a sidewall of the gate electrode 300 are also aligned.

Referring to FIG. 2N, a fifth dielectric layer 700e is formed on the exposed portion of the dielectric layer 100 to cover the sidewalls of the gate electrode 300, the sidewalls of the ferroelectric layer 400, the sidewall of the first hydrogen blocking pattern 500a, the sidewall of the second hydrogen blocking pattern 500b, the sidewall of the source pattern 600a, the sidewall of the drain pattern 600b, the sidewalls of the first dielectric layer 700a, and the sidewalls of the fourth dielectric layer 700d. In some embodiments, the fifth dielectric layer 700e is a part of one of the dielectric layers 36 of the interconnect structure 30 of FIG. 1, so the detailed description thereof is omitted herein.

Referring to FIG. 2O, a plurality of openings OP2 is formed in the fourth dielectric layer 700d and the first dielectric layer 700a. For example, the openings OP2 penetrate through the fourth dielectric layer 700d and the first dielectric layer 700a to expose at least a portion of the source pattern 600a and at least a portion of the drain pattern 600b. In some embodiments, the openings OP2 are formed through a photolithography and etching process. The etching process includes, for example, an anisotropic etching process such as dry etch or an isotropic etching process such as wet etch.

Referring to FIG. 2P, a plurality of conductive contacts 1000 is formed in the openings OP2. In some embodiments, each conductive contact 1000 includes a liner layer 1000a and a conductive layer 1000b. In some embodiments, the liner layer 1000a wraps around the conductive layer 1000b. For example, the liner layer 1000a covers a bottom surface and sidewalls of the conductive layer 1000b. In some embodiments, the liner layer 1000a is formed between the conductive layer 1000b and the fourth dielectric layer 700d and between the conductive layer 1000b and the first dielectric layer 700a to avoid diffusion of atoms between elements. In some embodiments, materials of the liner layer 1000a includes TiN, TaN, TiSiN, TaSiN, WSiN, TiC, TaC, TiAlC, TaAlC, TiAlN, TaAlN, or a combination thereof. On the other hand, materials of the conductive layer 1000b include, for example, tungsten, aluminum, copper, titanium, tantalum, titanium nitride, tantalum nitride, alloys therefore, and/or multi-layers thereof. In some embodiments, the conductive contacts 1000 are formed to fill up the openings OP2. For example, the liner layer 1000a and the conductive layer 1000b may be filled into the openings OP2 through CVD, ALD, plating, or other suitable deposition techniques to form the conductive contacts 1000. As illustrated in FIG. 2P, the conductive contacts 1000 penetrate through the fourth dielectric layer 700d and the first dielectric layer 700a to be in physical contact with the source pattern 600a and the drain pattern 600b. In some embodiments, the conductive contacts 1000 may serve as a bit line for the memory cells described above. It should be noted that in some embodiments, the liner layer 1000a is optional.

Referring to FIG. 2Q, a sixth dielectric layer 700f and a plurality of conductive patterns 1100 are formed on the fourth dielectric layer 700d, the fifth dielectric layer 700e, and the conductive contacts 1000 to obtain the second transistor T2. In some embodiments, the sixth dielectric layer 700f is a part of one of the dielectric layers 36 of the interconnect structure 30 of FIG. 1, so the detailed description thereof is omitted herein. In some embodiments, materials of the first dielectric layer 700a, the third dielectric layer 700c, the fourth dielectric layer 700d, the fifth dielectric layer 700e, and the sixth dielectric layer 700f may be the same. As such, the first dielectric layer 700a, the third dielectric layer 700c, the fourth dielectric layer 700d, the fifth dielectric layer 700e, and the sixth dielectric layer 700f may be considered as one bulk dielectric layer 700. In some embodiments, the dielectric layer 700 may be referred to as an inter-layer dielectric layer (ILD). As illustrated in FIG. 2Q, the dielectric layer 700 is in physical contact with both sidewalls SW_{900b} of each of the fins 900b of the channel layer 900. That is, the dielectric layer 700 covers the inner sidewalls ISW₉₀₀ and the outer sidewalls OSW₉₀₀ of the channel layer 900. In some embodiments, the dielectric layer 700 may correspond to one or two of the dielectric layers 36 of the interconnect structure 30 of FIG. 1.

As illustrated in FIG. 2Q, the conductive patterns 1100 are embedded in the fifth dielectric layer 700f and are in physical contact with the conductive contacts 1000. In some embodiments, each conductive pattern 1100 includes a liner layer 1100a and a conductive layer 1100b. In some embodiments, the liner layer 1100a wraps around the conductive layer 1100b. For example, the liner layer 1100a covers a bottom surface and sidewalls of the conductive layer 1100b. In some embodiments, the liner layer 1100a is formed between the conductive layer 1100b and the fourth dielectric layer 700d, between the conductive layer 1100b and the fifth dielectric layer 700e, and between the conductive layer 1100b and the sixth dielectric layer 700f to avoid diffusion of atoms between elements. In some embodiments, materials of the liner layer 1100a includes TiN, TaN, TiSiN, TaSiN, WSiN, TiC, TaC, TiAlC, TaAlC, TiAlN, TaAlN, or a combination thereof. On the other hand, materials of the conductive layer 1100b include, for example, tungsten, aluminum, copper, titanium, tantalum, titanium nitride, tantalum nitride, alloys therefore, and/or multi-layers thereof. In some embodiments, the liner layer 1100a and the conductive layer 1100b are deposited through CVD, ALD, plating, or other suitable deposition techniques to form the conductive patterns 1100. It should be noted that in some embodiments, the liner layer 1100a is optional.

It should be noted that although FIG. 2P and FIG. 2Q illustrated that the conductive contacts 1000 and the conductive patterns 1100 are formed in different steps, the disclosure is not limited thereto. In some alternative embodiments, the conductive contacts 1000 and the conductive patterns 1100 may be formed simultaneously in a same step.

Referring to FIG. 2P, FIG. 2Q, and FIG. 1, some of the conductive vias 32 shown in FIG. 1 may serve as the conductive contacts 1000 to electrically connect the second transistor T2 with the conductive patterns 34. That is, the conductive patterns 1100 may be some of the conductive patterns 34 in FIG. 1. In other words, the second transistor T2 is electrically connected to the first transistor T1 and/or the conductive terminals 80 through the conductive vias 32 and the conductive patterns 34 of the interconnect structure 30.

In some embodiments, since the second transistor T2 includes the ferroelectric layer 400, the second transistor T2 may be referred to as a FeFET (Ferroelectric Field-Effect Transistor). As mentioned above, the second transistor T2 is embedded in the interconnect structure 30, which is being considered as formed during back-end-of-line (BEOL) process. As such, the second transistor T2 is being considered as formed during BEOL process. In some embodiments, the second transistor T2 may be referred to as a bottom gate transistor or a back gate transistor.

In some embodiments, the second transistor T2 illustrated in FIG. 2Q is one of the examples of the second transistors T2 in FIG. 1. In some alternative embodiments, the second transistors T2 in FIG. 1 may be replaced by other transistors, such as a second transistor T2A shown in FIG. 3.

FIG. 3 is a cross-sectional view of the second transistor T2A in FIG. 1 in accordance with some alternative embodiments of the disclosure. Referring to FIG. 3, the second transistor T2A in FIG. 3 is similar to the second transistor T2 in FIG. 2Q, so similar elements are denoted by the same reference numeral, and the detailed description thereof is omitted herein. The difference between the second transistor T2A in FIG. 3 and the second transistor T2 in FIG. 2Q lies in that the hydrogen blocking layer 500 in the second transistor T2 in FIG. 2Q is omitted in the second transistor T2A in FIG. 3. That is, the source pattern 600a and the drain pattern 600b are in physical contact with the ferroelectric layer 400.

As illustrated in FIG. 3, the channel layer 900 is disposed on the ferroelectric layer 400. In addition, the channel layer 900 is disposed aside the source pattern 600a and the drain pattern 600b. For example, the bottom surface B₉₀₀ of the channel layer 900 (i.e. the bottom surface B₉₀₀ₐ of the base 900a) is coplanar with a bottom surface B₆₀₀ₐ of the source pattern 600a and a bottom surface B_{600b} of the drain pattern 600b. In other words, the channel layer 900 is not located vertically between the source pattern 600a/drain pattern 600b and the ferroelectric layer 400. That is, a distance between the top electrode (i.e. the source pattern 600a and the drain pattern 600b) and the storage layer (i.e. the ferroelectric layer 400) is rather short to provide a strong electric field from the top electrode (i.e. the source pattern 600a and the drain pattern 600b) to the storage layer (i.e. the ferroelectric layer 400). As such, the configuration of the channel layer 900 as shown in FIG. 3 may enhance the efficiency and the performance of the memory cells in the second transistor T2A.

In accordance with some embodiments of the disclosure, a transistor includes a gate electrode, a ferroelectric layer, a source pattern, a drain pattern, and a channel layer. The ferroelectric layer is disposed on the gate electrode. The source pattern and the drain pattern are disposed over the ferroelectric layer. The channel layer has a base and fins protruding from the base. The base is in contact with the ferroelectric layer, and the fins are located between the source pattern and the drain pattern.

In accordance with some embodiments of the disclosure, an integrated circuit includes a substrate, a first transistor, and an interconnect structure. The first transistor is over the substrate. The interconnect structure is disposed on the substrate. The interconnect structure includes dielectric layers and a second transistor embedded in the dielectric layers. The second transistor includes a gate electrode, a ferroelectric layer, a source pattern, a drain pattern, and a channel layer. The ferroelectric layer is disposed on the gate electrode. The source pattern and the drain pattern are disposed over the ferroelectric layer. The channel layer is disposed on the ferroelectric layer. The channel layer exhibits a U-shape from a cross-sectional view.

In accordance with some embodiments of the disclosure, a manufacturing method of a transistor includes at least the following steps. A gate electrode is provided. A ferroelectric layer and a source/drain material layer are formed on the gate electrode. A first dielectric layer, an etch stop layer, and a second dielectric layer are sequentially formed on the source/drain material layer. The second dielectric layer, the etch stop layer, the first dielectric layer, and the source/drain material layer are patterned to form an opening, a source pattern, and a drain pattern. The opening exposes the ferroelectric layer. A channel material layer is conformally deposited on the second dielectric layer and in the opening. The second dielectric layer and a portion of the channel material layer are removed until the etch stop layer is exposed, so as to form a channel layer. The etch stop layer is removed. A third dielectric layer is formed to cover the first dielectric layer and the channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
a gate electrode;
a ferroelectric layer disposed on the gate electrode;
a source pattern and a drain pattern disposed over the ferroelectric layer; and
a channel layer having a base and fins protruding from the base, wherein the base is in contact with the ferroelectric layer, and the fins are located between the source pattern and the drain pattern.

2. The transistor of claim 1, further comprising a hydrogen blocking layer sandwiched between the source pattern and the ferroelectric layer and sandwiched between the drain pattern and the ferroelectric layer.

3. The transistor of claim 2, wherein the hydrogen blocking layer comprises a first hydrogen blocking pattern and a second hydrogen blocking pattern, and the fins are located between the first hydrogen blocking pattern and the second hydrogen blocking pattern.

4. The transistor of claim 3, wherein the first hydrogen blocking pattern and the second hydrogen blocking pattern are in contact with the base and the fins.

5. The transistor of claim 2, wherein a bottom surface of the base is coplanar with a bottom surface of the hydrogen blocking layer.

6. The transistor of claim 1, further comprising a dielectric layer, wherein the dielectric layer is in contact with both sidewalls of each of the fins.

7. The transistor of claim 1, wherein the source pattern and the drain pattern are in contact with the fins.

8. The transistor of claim 1, wherein a bottom surface of the base is coplanar with a bottom surface of the source pattern and a bottom surface of the drain pattern.

9. The transistor of claim 1, wherein the fins extend from the base to beyond a top surface of the source pattern and a top surface of the drain pattern.

10. An integrated circuit, comprising:
a substrate;
a first transistor over the substrate; and
an interconnect structure disposed on the substrate, comprising;
dielectric layers; and
a second transistor embedded in the dielectric layers, comprising:
a gate electrode;
a ferroelectric layer disposed on the gate electrode;
a source pattern and a drain pattern disposed over the ferroelectric layer; and
a channel layer disposed on the ferroelectric layer, wherein the channel layer exhibits a U-shape from a cross-sectional view.

11. The integrated circuit of claim 10, wherein the second transistor further comprises a hydrogen blocking layer sandwiched between the source pattern and the ferroelectric layer and sandwiched between the drain pattern and the ferroelectric layer.

12. The integrated circuit of claim 11, wherein the hydrogen blocking layer comprises a first hydrogen blocking pattern and a second hydrogen blocking pattern, and the first hydrogen blocking pattern and the second hydrogen blocking pattern are respectively in contact with opposite outer sidewalls of the channel layer.

13. The integrated circuit of claim 11, wherein a bottom surface of the channel layer is coplanar with a bottom surface of the hydrogen blocking layer.

14. The integrated circuit of claim 10, wherein one of the dielectric layers covers inner sidewalls and outer sidewalls of the channel layer.

15. The integrated circuit of claim 10, wherein the source pattern and the drain pattern are respectively in contact with opposite outer sidewalls of the channel layer.

16. The integrated circuit of claim 10, wherein a bottom surface of the channel layer is coplanar with a bottom surface of the source pattern and a bottom surface of the drain pattern.

17. A manufacturing method of a transistor, comprising:
providing a gate electrode;
forming a ferroelectric layer and a source/drain material layer on the gate electrode;
sequentially forming a first dielectric layer, an etch stop layer, and a second dielectric layer on the source/drain material layer;
patterning the second dielectric layer, the etch stop layer, the first dielectric layer, and the source/drain material layer to form an opening, a source pattern, and a drain pattern, wherein the opening exposes the ferroelectric layer;
conformally depositing a channel material layer on the second dielectric layer and in the opening;
removing the second dielectric layer and a portion of the channel material layer until the etch stop layer is exposed, so as to form a channel layer;
removing the etch stop layer; and
forming a third dielectric layer to cover the first dielectric layer and the channel layer.

18. The method of claim 17, further comprising:
forming a hydrogen blocking layer between the ferroelectric layer and the source/drain material layer, wherein the opening is formed by further patterning the hydrogen blocking layer.

19. The method of claim 17, further comprising:
forming conductive contacts penetrating through the first dielectric layer and the third dielectric layer to be in physical contact with the source pattern and the drain pattern.

20. The method of claim 17, wherein the channel layer is formed to exhibit a U-shape in a cross-sectional view.
